(19) United States
(12) Patent Application Publication
(10) Pub. No.: US 2003/0194494 A1
(43) Pub. Date: Oct. 16, 2003

(54) Method for forming soldering layer of fiber arrays

(75) Inventors: Chung-I Chiang, Taoyuan (TW); Ming-Jen Wang, Tucheng City (TW); Kun-Hsien Cheng, Jungli City (TW); Hong-Jueng King, Taoyuan (TW); Huei-Pin Huang, Taoyuan (TW); Chwei-Jing Yeh, Sanchung City (TW)

Correspondence Address: BACON & THOMAS, PLLC, 625 SLATERS LANE, FOURTH FLOOR, ALEXANDRIA, VA, 22314

(73) Assignee: RiTek Corporation, Hsinchu (TW)

(21) Appl. No.: 10/411,257

(22) Filed: Apr. 11, 2003

(30) Foreign Application Priority Data
Apr. 12, 2002 (TW) 91107518

(51) Int. Cl. C23C 14/00; B05D 3/10; B05D 1/36; B05D 1/18

(52) U.S. Cl. 427/250; 204/192.1; 427/404; 427/304; 427/438; 427/405; 427/437

(57) ABSTRACT

ABSTRACT OF THE DISCLOSURE A method for forming the soldering layer of fiber array substrate surface has been disclosed herein. A plurality of fiber array bases having V-shape grooves are formed on a substrate, and a solder layer is formed on the whole substrate via chemical plating method of following steps: forming a layer of nickel/chromium (Ni/Cr) alloy or aluminum (Al) metal on said substrate through evaporation or sputtering; treating said surface of said substrate having V-shape grooves with a sensitizing solution for plating said surface with Sn²⁺, wherein said sensitizing solution comprises deionized water and SnCl₂; treating said sensitized surface of said substrate with an activating solution for precipitating catalytic element Pd⁰ on said surface, wherein said sensitizing solution comprises 2 to 10 g/l of PdCl₂ and 0.01 to 0.1 M HCl; and (E) immersing said treated surface into an electroless nickel plating solution to form a nickel metal layer on said treated surface.

### BACKGROUND OF THE INVENTION

1. Field of the Invention

The present invention relates to a surface treating method and, more particularly, to a surface treating method suitable for forming a solder layer on the substrate surface of fiber arrays.

2. Description of Related Art

In recent years, optical fibers are intensively used as signal transmission media in optical communication. By matching with the development of high-channel-counts-plane-wave-guides and that of dense-wavelength-DeMux/Mutiplexer-DWDM, the communication through optical fibers can meet the demand for transmitting high-volume-data in high speed in internet communication and broadband communication. In most cases, plane-wave-guides of high channel counts containing at least a fiber array are commonly used or sandwiched between related photoelectric components for transmitting signals between those photoelectric components. A conventional fiber array module generally comprises a fiber array substrate having a plurality of V-grooves for receiving and holding optical fibers and keeping loaded optical fibers in accurate aligned positions.

The traditional method for producing the fiber array module is carried out by fixing naked optic fibers extended from ribbons on a base having grooves, and then curing sputtered or evaporated binders in the grooves. After placing a cover on said substrate, this combined assembly of the fiber array base, the cover and the optical fibers is pressed, and exposed to light, or heated for curing and fixing. However, the conventional sputtered or evaporated binder has low resistance to the environmental oxidation or erosion. The process for coating conventional sputtered or evaporated binder on said substrate is not suitable for mass-production. So it is desired to develop a new method to form a metal solder layer on the surface of the fiber array to mitigate and/or obviate the aforementioned problems.

### SUMMARY OF THE INVENTION

The object of the present invention is to provide a method for forming a solder layer on the substrate surface of fiber arrays, which is simple and suitable for mass production. In addition, this method costs low and saves much time for fabrication.

To achieve the object, the method for forming a solder layer of fiber arrays of the present invention includes following steps: (A) forming a plurality of fiber array bases having V-grooves on a Si or Pyrex glass substrate; (B) forming a layer of nickel/chromium (Ni/Cr) alloy or aluminum (Al) metal on said substrate through evaporation or sputtering; (C) treating said surface of said substrate having V-shape grooves with a sensitizing solution for plating said surface with Sn²⁺, wherein said sensitizing solution comprises deionized water and SnCl₂; (D) treating said sensitized surface of said substrate with an activating solution for precipitating catalytic element Pd⁰ on said surface, wherein said sensitizing solution comprises 2 to 10 g/l of PdCl₂ and 0.01 to 0.1 M HCl; and (E) immersing said treated surface into an electroless nickel plating solution to form a nickel metal layer on said treated surface.

The method of the present invention optionally includes step (F) treating said substrate surface with an electroless gold plating solution to precipitate a gold metal layer with sufficient thickness on said nickel metal layer to prevent said nickel metal layer from oxidation.

Other objects, advantages, and novel features of the invention will become more apparent from the following detailed description when taken in conjunction with the accompanying drawings.

### BRIEF DESCRIPTION OF THE DRAWINGS

FIG. 1 is a top view of the bases having grooves on a silicon wafer of the present invention;

FIG. 2 is a cross-section view of the silicon wafer used in the method of the present invention.

### DETAILED DESCRIPTION OF THE PREFERRED EMBODIMENT

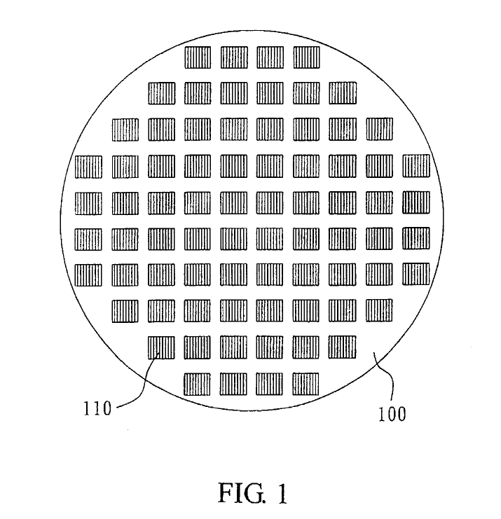

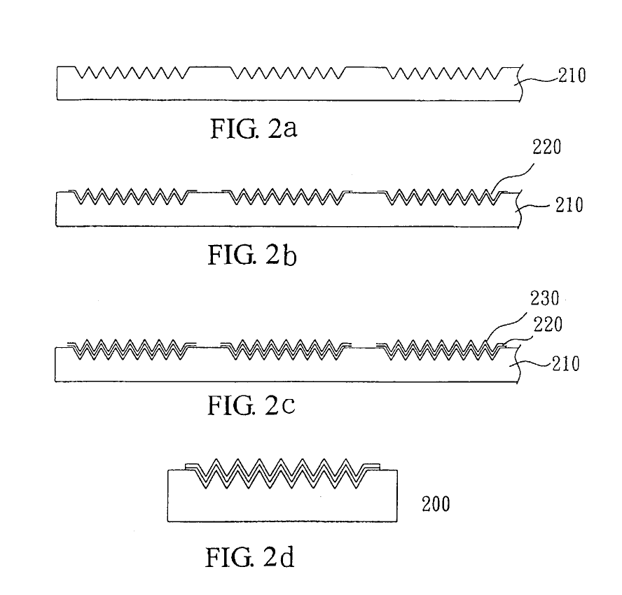

The method for forming the grooves of the substrate of the present invention is not limited. Preferably, the grooves of the substrate are formed through dicing, cutting or etching (with reference of FIG. 1). In most cases, bases 110 with a plurality of grooves are formed on a silicon wafer substrate 100 first for mass production. After the formation of metal layer is achieved, the substrate 100 was then diced or cut into fiber array base units 200 (please refer to FIG. 2d). The surface of the groove of the substrate of the present invention is immersed in a solution of 1 g/L (6.4×10⁻³M) of SnCl₂ for 5 to 10 minutes with gently stirring. Through the immersing, Sn²⁺ ions are adsorbed on the surface of the substrate without any physical abrasions. In most cases, the solution of 1 g/L of SnCl₂ is prepared by adding 300 ml of crystalline SnCl₂ into 300 g of 18 Ω water and stirring for around 3 minutes to form a clear, colorless SnCl₂ solution. This SnCl₂ solution is stored under N₂ atmosphere before use. The sensitized substrate surface is subsequently immersed into water twice and then subjecting to an activating solution, which contains 6 g/L (3.4×10⁻² M) of PdCl₂ and 0.02 M HCl, for 1 min with gently stirring.

For adjusting the sensitization to an optimal condition, the concentration effect of PdCl₂ and HCl is considered and studied. The studied results show that high concentration of PdCl₂ is beneficial to the sensitization. In contrast, the high concentration of HCl does not result in similar effect. Even though less concentration of HCl does better, the concentration of the HCl should still be kept in sufficient concentration to dissolve PdCl₂. Generally speaking, the concentration of Pd of PdCl₂ ranging from 2 g/L to 10 g/L can be used. Preferably, the concentration of Pd of PdCl₂ is 6 g/L. The other things to be kept in mind is that the Sn²⁺ ions absorbed on the surface are easily oxidized and deadsorbed when the treated substrate is transferred to PdCl₂ solution since Sn²⁺ competes against the reduction of Pd²⁺. On the other hand, high-quality nickel-plating layer can be formed when PdCl₂ is in a concentration of 6 g/L and HCl is in a concentration of 0.02 to 0.05 M. But only partial nickel layer are formed when HCl is 0.1 M. Therefore, the concentration of HCl should be kept as low as possible but sufficient to dissolve PdCl₂.

Suitable commercial electroless nickel solution used here usually contains two parts, i.e. Solution A and Solution B. They are mixed just before use. Solution A provides Ni²⁺ ions. Solution A here is solutions containing Ni²⁺ ions such as nickel chloride, nickel sulfide, and nickel acetate. Solution B is a solution, which provides hypophosphite group, such as sodium hypophosphite. In one example of the nickel plating solution used here, Solution A is a solution containing nickel sulfide and Solution B is a solution containing sodium hypophosphite, sodium hydroxide and acetic acid. The nickel-plating solution is prepared by mixing the Solution A, the Solution B and water together. The adequate pH of the solution ranges from 4.5 to 5.2. The nickel-containing solution used in the metallization process is prepared by mixing Solution A, Solution B and 18 MΩ of water in a ratio of 1:3:16. The solution is then filtrated with Halgne Media-Plus filtering unit (Nylon with 0.2 μm pore size) after it is made. The pH of this solution is about 4.85, and the temperature for plating said nickel layer is about 85° C. The controlling of the temperature here is very important because nickel will plate on the container wall at high temperature spontaneously. On the contrary, the plating rate will dramatically decreases as the plating is achieved at low temperature. The temperature gradient from the top to the bottom of the container is required to be above 1 to 2° C. The spontaneous plating occurs when the gradient is above 10° C. In most cases, the spontaneous plating of nickel will cause rapid accumulation of nickel and production of hydrogen gas. Furthermore, the bubble of the hydrogen gas in the solution will adhere to the substrate surface and prevent the deposition of the nickel layer plating. For controlling the temperature well, a container installed with nickel-containing solution is put into a larger container installed with water at the bottom and equipped a stirring bar. Then the large container is mounted on a fluoroware cage. The water of the water bath surrounding the container installed with nickel containing solution is used to precisely control the temperature of solution. Consequently, the spontaneous plating seldom occurs within 6 hours.

The method for forming a soldering layer on the surface of fiber array substrate of the present invention can be illustrated through the referred figures (FIG. 2a-FIG. 2d). A plurality of chips 210 with grooves are formed on a wafer or a Pyrex glass substrate (please refer to FIG. 2a). A nickel layer 220 (even the gold layer 230) is subsequently plated on the wafer or Pyrex glass substrate 210 through chemical method (please refer to FIGS. 2b and 2c). The wafer or Pyrex glass substrate 210 is then divided (please refer to FIG. 2d) to form a number of fiber array bases, which have nickel-soldering layer.

After plating the nickel layer, a gold layer is optionally plated on the nickel layer. The electroless plating of the gold layer is performed by rinsing the substrate with a nickel layer, and the substrate is then immersed into an electroless gold bath, whose pH ranges from 5.0 to 7.2, for 10 minutes at 70° C. The solution is gently stirred, and then a gold layer with a thickness of 0.18 μm is formed on the nickel layer. The commercial solution used for electroless gold plating solution is purified before use.

Embodiment 1

The moralization of the surface includes the following steps: (A) providing a container for storing SnCl₂ solution in a water bath, a container for storing deionized water, and a for storing with a PdCl₂ and HCl; (B) immersing a evaporated or sputtered substrate with cut bases having grooves into a sensitizing solution which contains 1 g/L of SnCl₂ for 5 to 10 minutes, and rinsing the substrate with deionized water for at least one time; (C) immersing the sensitized substrate surface into an activating solution containing 6 g/L of PdCl₂ and 0.02 M of HCl for 1 min at room temperature and rinsing it with deionized water twice; (D) drying the activated surface with 75° C. flowing gas for 5 to 10 minutes; (E) immersing the activated substrate into an electroless nickel plating solution for about 20 minutes and keeping the temperature at 85±1° C. followed by rinsing with deionized water; (F) immersing the nickel-plated substrate into an electroless gold plating solution for about 10 minutes with gently stirring at 70° C., followed by rinsing with deionized water; after that, if it's necessary, drying the substrate at 75° C. with flowing gas for about 10 minutes. Finally, a plate having bases with a solder layer on the surface of fiber array substrate are obtained and re ready for dicing into small pieces.

Although the present invention has been explained in relation to its preferred embodiment, it is to be understood that many other possible modifications and variations can be made without departing from the spirit and scope of the invention as hereinafter claimed.

What is claimed is:

1. A method for forming a solder layer on the surface of fiber array substrate, comprising the following steps:
(a) forming a plurality of fiber array bases having V-grooves on one surface of a substrate;
(b) forming a nickel/chromium (Ni/Cr) alloy or aluminum (Al) metal layer on said substrate through evaporation or sputtering method;
(c) treating said surface of said substrate having V-shape grooves with a sensitizing solution for plating said surface with Sn²⁺, wherein said sensitizing solution comprises deionized water and SnCl₂;
(d) immersing said treated surface into an electroless nickel-plating solution to form a nickel metal layer on said treated surface.

2. The method as claimed in claim 1, wherein the thickness of said metal layer in step (B) ranges from 0.2 to 0.5 μm.

3. The method as claimed in claim 1, further comprising step (F) treating said substrate surface with an electroless gold plating solution to precipitate a gold metal layer with sufficient thickness on said nickel metal layer to prevent said nickel metal layer from oxidation.

4. The method as claimed in claim 1, wherein said V-grooves are formed by dicing, cutting or etching.

5. The method as claimed in claim 1, wherein said SnCl₂ sensitizing solution comprises 0.5 to 3 g/l of SnCl₂.

6. The method as claimed in claim 1, wherein the concentration of HCl in said PdCl₂ activating solution ranges from 0.02 to 0.05 M.
